(19) United States
(12) Patent Application Publication
(10) Pub. No.: US 2017/0117039 A1
(43) Pub. Date: Apr. 27, 2017

(54) NONVOLATILE SEMICONDUCTOR MEMORY DEVICE AND METHOD OF CONTROLLING THE SAME

(71) Applicant: Kabushiki Kaisha Toshiba, Minato-ku (JP)

(72) Inventors: Masaki YAMATO, Yokkaichi (JP); Takeshi YAMAGUCHI, Yokkaichi (JP); Takeshi TAKAGI, Yokkaichi (JP); Hiroyuki ODE, Yokkaichi (JP); Toshiharu TANAKA, Yokkaichi (JP)

(73) Assignee: Kabushiki Kaisha Toshiba, Minato-ku (JP)

(21) Appl. No.: 15/070,526

(22) Filed: Mar. 15, 2016

Related U.S. Application Data
(60) Provisional application No. 62/246,877, filed on Oct. 27, 2015.

(51) Int. Cl. G11C 13/00

(52) U.S. Cl. CPC G11C 13/004

(57) ABSTRACT

According to an embodiment, a nonvolatile semiconductor memory device comprises: a memory cell array; and a control circuit that manages a setting operation and a read operation. The memory cell array comprises: a first wiring line; a second wiring line intersecting the first wiring line; and a memory cell including a variable resistance element and a nonlinear element. The variable resistance element is configured having a first metal film, a first variable resistance film, a second variable resistance film, and a second metal film stacked and disposed therein in this order. A work function of the second metal film is smaller than a work function of the first metal film.

### CROSS REFERENCE TO RELATED APPLICATION

This application is based upon and claims the benefit of priority from U.S. Provisional Patent Application No. 62/246,877, filed on Oct. 27, 2015, the entire contents of which are incorporated herein by reference.

### FIELD

Embodiments described herein relate to a nonvolatile semiconductor memory device and a method of controlling the same.

### BACKGROUND

In recent years, ReRAM (Resistive RAM) that utilizes as memory a variable resistance element whose resistance value is reversibly changed, has been proposed. This kind of nonvolatile semiconductor memory device employs a nonlinear element having a saturation curve, such as a transistor or diode.

### BRIEF DESCRIPTION OF THE DRAWINGS

FIG. 1 is an example of a block diagram of a nonvolatile semiconductor memory device according to a first embodiment.

FIG. 2 is a perspective view of part of the memory cell array 1.

FIG. 3 is a schematic view showing a schematic configuration of a memory cell MC according to the first embodiment.

FIGS. 4A to 4F are graphs showing a relationship between a saturation curve of a nonlinear element and a current flowing in the memory cell MC.

FIG. 5 is a graph showing a relationship between a voltage V_{Set} during setting and a voltage V_{Read} during read.

FIG. 6 is an energy band diagram showing an energy level when a resistance varying element VR according to the present embodiment is applied with the setting voltage V_{Set}.

FIG. 7 is an energy band diagram showing an energy level when the resistance varying element VR according to the present embodiment is applied with the read voltage V_{Read}.

FIG. 8 is a schematic perspective view showing an example of configuration of a nonvolatile semiconductor memory device according to a second embodiment.

FIG. 9 is a schematic cross-sectional view showing an example of configuration of a memory cell MC according to the second embodiment.

### DETAILED DESCRIPTION

A nonvolatile semiconductor memory device according to an embodiment includes: a memory cell array; and a control circuit that applies a voltage to the memory cell array to manage a setting operation and a read operation. The memory cell array includes: a first wiring line; a second wiring line intersecting the first wiring line; and a memory cell disposed at an intersection of the first and second wiring lines and including a variable resistance element and a nonlinear element. The variable resistance element is configured having a first metal film, a first variable resistance film, a second variable resistance film, and a second metal film stacked and disposed therein in this order. A work function of the second metal film is smaller than a work function of the first metal film.

### First Embodiment

[Configuration]

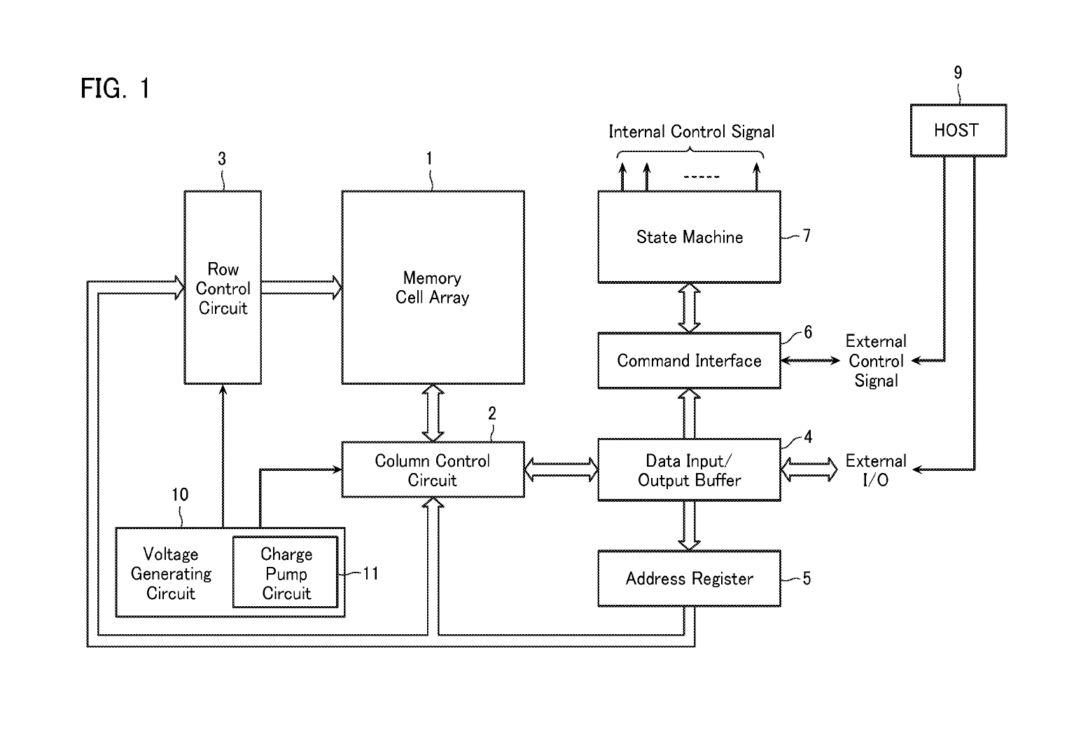

FIG. 1 is a block diagram of a nonvolatile semiconductor memory device according to a first embodiment. This nonvolatile semiconductor memory device includes a memory cell array 1 that has a plurality of memory cells MC disposed in a matrix therein, and that comprises a bit line BL and a word line WL disposed orthogonally to each other to be connected to the memory cell MC. Provided in a periphery of this memory cell array 1 are a column control circuit 2 and a row control circuit 3. The column control circuit 2 controls the bit line BL and performs data erase of the memory cell (a resetting operation), data write to the memory cell (a setting operation), and data read from the memory cell (a read operation). The row control circuit 3 selects the word line WL and applies a voltage for data erase of the memory cell, data write to the memory cell, and data read from the memory cell.

A data input/output buffer 4 is connected to an external host 9, via an I/O line, and receives write data, receives an erase command, outputs read data, and receives address data or command data. The data input/output buffer 4 sends received write data to the column control circuit 2, and receives data read from the column control circuit 2 to be outputted to external. Address data supplied to the data input/output buffer 4 from external is sent to the column control circuit 2 and the row control circuit 3 via an address register 5.

Moreover, a command supplied to the data input/output buffer 4 from the host 9 is sent to a command interface 6. The command interface 6 receives an external control signal from the host 9, determines whether data inputted to the data input/output buffer 4 is write data or a command or an address, and, if a command, receives the data and transfers the data to a state machine 7 as a command signal.

The state machine 7 performs management of this nonvolatile semiconductor memory device overall, receives the command from the host 9, via the command interface 6, and performs management of read, write, erase, input/output of data, and so on.

In addition, it is also possible for the external host 9 to receive status information managed by the state machine 7 and judge an operation result. Moreover, this status information is utilized also in control of write and erase.

Furthermore, the state machine 7 controls a voltage generating circuit 10. This control enables the voltage generating circuit 10 to output a pulse of any voltage and any timing. Moreover, the voltage generating circuit 10 comprises a charge pump circuit 11 that boosts an inputted voltage, such as a power supply voltage, to output a voltage larger than the inputted voltage.

Now, the pulse formed by the voltage generating circuit 10 can be transferred to any wiring line selected by the column control circuit 2 and the row control circuit 3. These column control circuit 2, row control circuit 3, state machine 7, voltage generating circuit 10, and so on, configure a control circuit in the present embodiment.

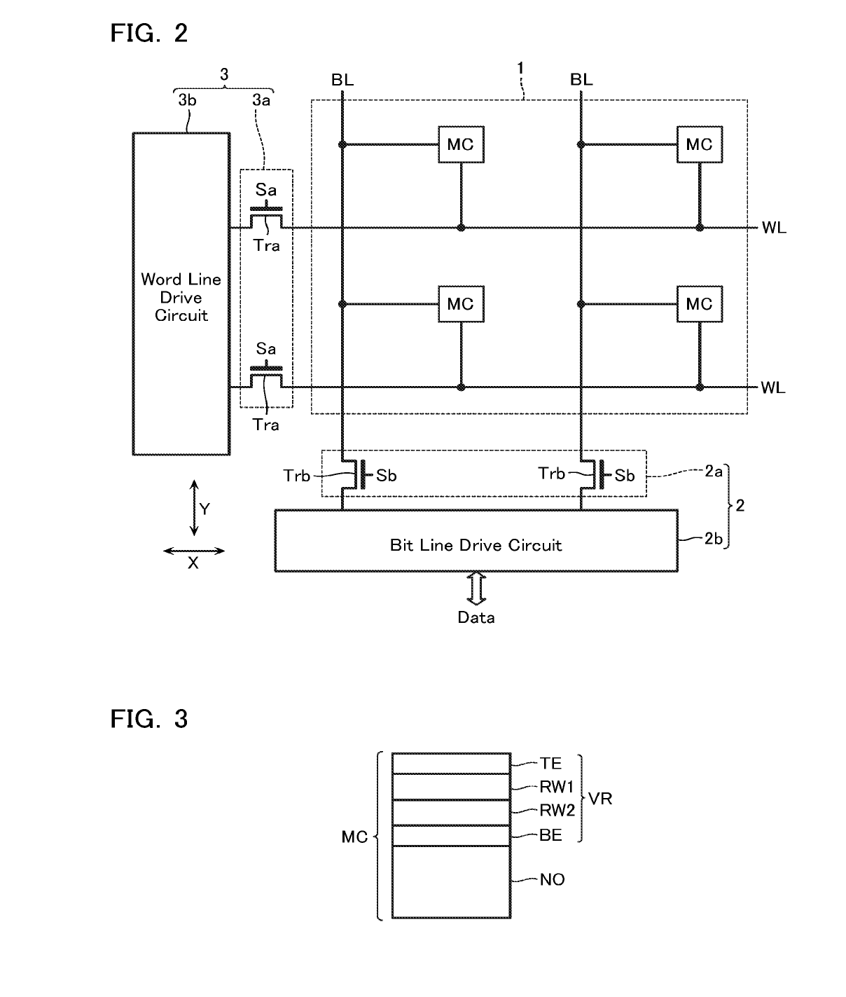

Next, a circuit configuration of the memory cell array 1 according to the present embodiment will be described with reference to FIG. 2. FIG. 2 is a circuit diagram showing a configuration of the memory cell array 1 according to the present embodiment.

As shown in FIG. 2, the memory cell array 1 includes: the word line WL and the bit line BL intersecting each other; and the memory cell MC disposed at an intersection of the word line WL and the bit line BL. The word lines WL are arranged with a certain pitch in a Y direction, and extend in an X direction. The bit lines BL are arranged with a certain pitch in the X direction, and extend in the Y direction. That is, the memory cells MC are disposed in a matrix on a plane formed by the X direction and the Y direction. A configuration of this memory cell MC will be mentioned later.

As shown in FIG. 2, the column control circuit 2 comprises: a bit line select circuit 2a that selects the bit line BL; and a bit line drive circuit 2b that drives the bit line BL.

As shown in FIG. 2, the bit line select circuit 2a includes a plurality of select transistors Trb. One end of the select transistor Trb is connected to one end of the bit line BL, and the other end of the transistor Trb is connected to the bit line drive circuit 2b. A gate of the select transistor Trb is supplied with a signal Sb. That is, the bit line select circuit 2a selectively connects the bit line BL to the bit line drive circuit 2b, according to the signal Sb.

As shown in FIG. 2, the bit line drive circuit 2b applies the bit line BL with a voltage required for data erase of the memory cell MC, data write to the memory cell MC, and data read from the memory cell MC. Moreover, the bit line drive circuit 2b outputs data read from the bit line BL to external.

The row control circuit 3 comprises: a word line select circuit 3a that selects the word line WL; and a word line drive circuit 3b that drives the word line WL.

As shown in FIG. 2, the word line select circuit 3a includes a plurality of select transistors Tra. One end of the select transistor Tra is connected to one end of the word line WL, and the other end of the select transistor Tra is connected to the word line drive circuit 3b. A gate of the select transistor Tra is supplied with a signal Sa. That is, the word line select circuit 3a selectively connects the word line WL to the word line drive circuit 3b, by controlling the signal Sa.

The word line drive circuit 3b applies the word line WL with a voltage required for data erase of the memory cell MC, data write to the memory cell MC, and data read from the memory cell MC.

[Configuration of Memory Cell MC]

Next, the configuration of the memory cell MC in the present embodiment will be described. As shown in FIG. 3, the memory cell MC is a bipolar type memory cell configured from a series-connected circuit of a variable resistance element VR and a nonlinear element NO. The variable resistance element VR nonvolatilely stores its resistance value as rewritable data.

The nonlinear element NO is a nonlinear element having a saturation curve, such as a diode or transistor, for example. Moreover, the variable resistance element VR and the nonlinear element NO are connected by unillustrated electrodes interposed between each.

[Variable Resistance Element VR]

Moreover, the variable resistance element VR according to the present embodiment is configured having stacked therein, from an upper portion, in the following order, a top electrode TE, a first variable resistance film RW1, a second variable resistance film RW2, and a bottom electrode BE. The top electrode TE and the bottom electrode BE are configured from a metal and function also as a barrier metal layer or an adhesive layer. In addition, a work function of the metal configuring the bottom electrode BE is smaller than a work function of the metal configuring the top electrode TE.

Usable as the metal configuring the top electrode TE are the likes of titanium nitride (TiN), platinum (Pt), ruthenium (Ru), or iridium (Ir), for example. Usable as the metal configuring the bottom electrode BE is a metal whose work function is smaller than that of the metal configuring the top electrode TE, such as tungsten nitride (WN) or tantalum nitride (TaN), for example.

Moreover, stacked between the top electrode TE and the bottom electrode BE are the first resistance varying film RW1 and the second resistance varying film RW2 that function as a memory film capable of storing writable data.

The first resistance varying film RW1 is configured from a metal oxide film of the likes of hafnium oxide (HfOₓ), for example. The first resistance varying film RW1 is formed by a method such as ALD (Atomic Layer Deposition), for example, and has a thickness which is about 5 nm, for example, but may be appropriately changed in a range of about 2 to 10 nm. Employable as a material besides HfOₓ are a transition metal oxide of the likes of chromium (Cr), tungsten (W), vanadium (V), niobium (Nb), tantalum (Ta), titanium (Ti), zirconium (Zr), scandium (Sc), yttrium (Y), thorium (Th), manganese (Mn), iron (Fe), ruthenium (Ru), osmium (Os), cobalt (Co), nickel (Ni), copper (Cu), zinc (Zn), cadmium (Cd), aluminum (Al), gallium (Ga), indium (In), tin (Sn), lead (Pb), and bismuth (Bi), or an oxide of the likes of a so-called rare earth element from lanthanum (La) to lutetium (Lu).

The second resistance varying film RW2 is configured from a silicon oxide (SiOₓ) film, for example. Similarly to the first resistance varying film RW1, this second resistance varying film RW2 is also formed by the likes of ALD, but has a thickness which is preferably 3 nm or less. This is because, if the thickness ends up exceeding 3 nm, then during a later-mentioned memory cell operation, a tunnel effect ends up decreasing and it ends up becoming difficult for electrons to pass through. As a result, there is a risk that deterioration of device characteristics is caused. Moreover, in order to lower a level of the first resistance varying film RW1 during the read operation, it is preferable for a material of low permittivity to be used as the second resistance varying film RW2. For example, the likes of alumina (AlO) or silicon nitride (SiN) may be used, besides the above-described silicon oxide.

As described above, the nonlinear element NO is an element having a saturation curve, such as a transistor or diode, and rectifies a current flowing in the memory cell. Connected to the nonlinear element NO are the likes of an unillustrated electrode or wiring line.

[Operation of Memory Cell]

The nonvolatile semiconductor memory device according to the present embodiment is of a so-called bipolar type. Therefore, write of data to the memory cell MC is performed by applying, for a certain time, to a selected memory cell MC, a voltage corresponding to a breakdown voltage in a reverse direction of the nonlinear element NO. As a result, the variable resistance element VR of the selected memory cell MC changes from a high resistance state to a low resistance state. Hereafter, this operation that changes the variable resistance element VR from a high resistance state to a low resistance state will be called a “setting operation”.

On the other hand, erase of data to the memory cell MC is performed by applying a certain voltage, for a certain time, in a forward direction of the nonlinear element NO, to the variable resistance element VR in a low resistance state after the setting operation. As a result, the variable resistance element VR changes from a low resistance state to a high resistance state. Hereafter, this operation that changes the variable resistance element VR from a low resistance state to a high resistance state will be called a “resetting operation”. For example, in the case of storage of binary data, it is performed by performing the resetting operation and the setting operation on the selected memory cell MC and thereby changing a resistance state of the variable resistance element VR of the selected memory cell MC to a high resistance state and a low resistance state.

Moreover, the variable resistance element VR according to the present embodiment requires forming to be performed at a time of use. Forming, similarly to the setting operation and resetting operation, is performed by continuing to apply a certain voltage for a certain time.

Moreover, in a read operation that determines whether data is recorded in the memory cell MC or not, the memory cell MC is applied with a read voltage V_{Read}. Then, a current flowing in the memory cell MC is detected by a sense amplifier. If the current detected by the sense amplifier is larger than a certain read current I_{Read}, then the variable resistance element VR of the memory cell MC is judged to be in a low resistance state (setting state), and if the current detected by the sense amplifier is smaller than the read current I_{Read}, then the variable resistance element VR of the memory cell MC is judged to be in a high resistance state (resetting state). Moreover, this read voltage during the read operation has a reverse polarity to the setting voltage.

[Setting Voltage]

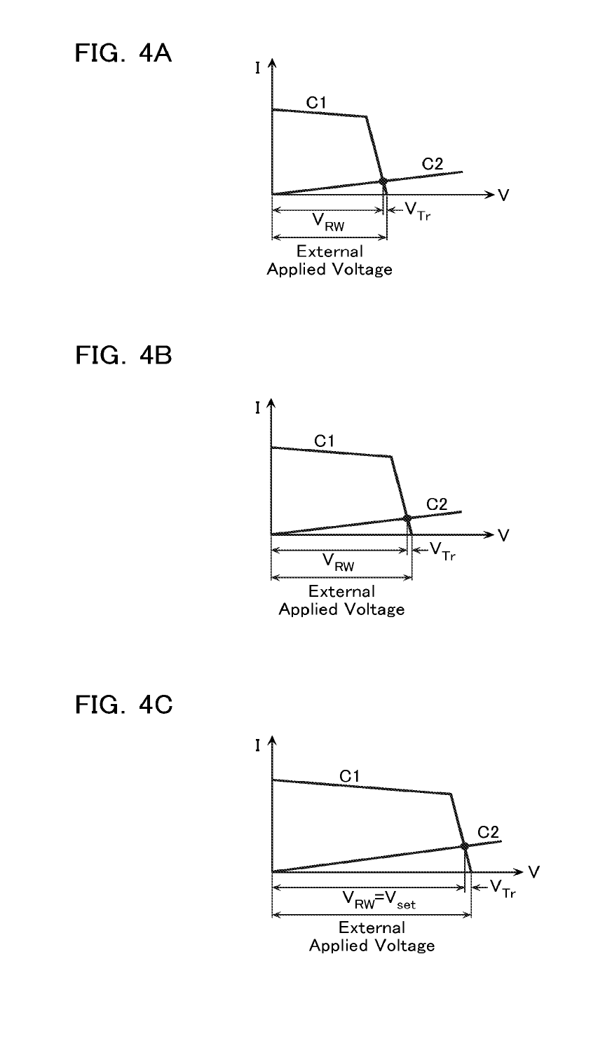

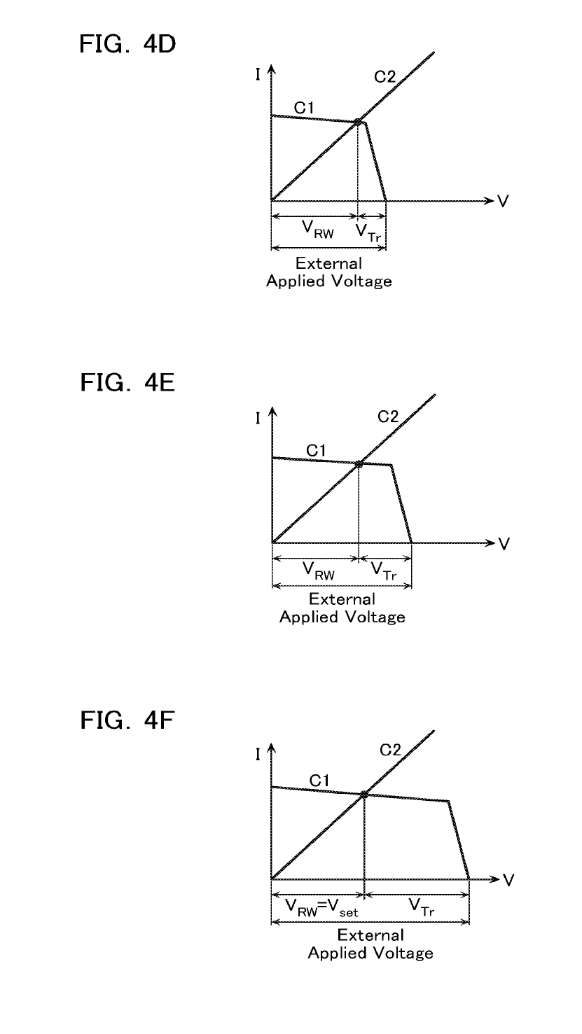

Next, a relationship between the setting voltage applied to the memory cell MC during the setting operation described above and current-voltage characteristics of the nonlinear element NO and the resistance varying films in the resistance varying element VR, will be described using FIGS. 4A to 4F.

In each of the drawings of FIGS. 4A to 4F, curves C1 and C2 show current-voltage characteristics of, respectively, the nonlinear element NO and the resistance varying films (RW1+RW2). As described above, the resistance varying element VR and the nonlinear element NO are connected in series, hence a current indicated by a point where the two intersect flows commonly. Moreover, the resistance varying films and the nonlinear element NO have only voltages indicated by V_{RW} and V_{Tr}, of an external applied voltage applied to the memory cell MC, respectively divided thereto.

The graphs shown in FIGS. 4A to 4C show the case where an inclination of a load curve C2 of the resistance varying films is small, and the load curve C2 and a linear region of a characteristic curve C1 of the nonlinear element NO intersect. Moreover, the external applied voltage is increased from FIG. 4A to FIG. 4C. As shown in FIG. 4C, the voltage V_{RW} applied to the resistance varying films is set when it has become equal to a setting voltage V_{Set}.

As shown in FIGS. 4A to 4C, when the load curve C2 of the resistance varying films intersects the linear region of the characteristic curve C1 of the nonlinear element NO, the current flowing in the memory cell MC becomes comparatively small. Therefore, the voltage V_{Tr} consumed by the nonlinear element NO in the external applied voltage applied to the memory cell MC also becomes small, hence the setting voltage V_{Set} can be applied to the resistance varying films without significantly increasing the external applied voltage.

On the other hand, the graphs shown in FIGS. 4D to 4F show the case where the inclination of the load curve C2 of the resistance varying films is large, and the load curve C2 and a saturation region of the characteristic curve C1 of the nonlinear element NO intersect. Moreover, the external applied voltage is increased from FIG. 4D to FIG. 4F. In this case also, similarly to in FIGS. 4A to 4C, the voltage V_{RW} applied to the resistance varying films is set when it has become equal to the setting voltage V_{Set}.

As shown in FIGS. 4D to 4F, when the load curve C2 of the resistance varying films intersects the saturation region of the characteristic curve C1 of the nonlinear element NO, the current flowing in the memory cell MC becomes comparatively larger compared to in FIGS. 4A to 4C. Thereupon, the voltage V_{Tr} consumed by the nonlinear element NO in the external applied voltage applied to the memory cell MC also becomes large, hence a large external applied voltage ends up becoming required in order to make the voltage V_{RW} applied to the resistance varying films equal to the setting voltage V_{Set}.

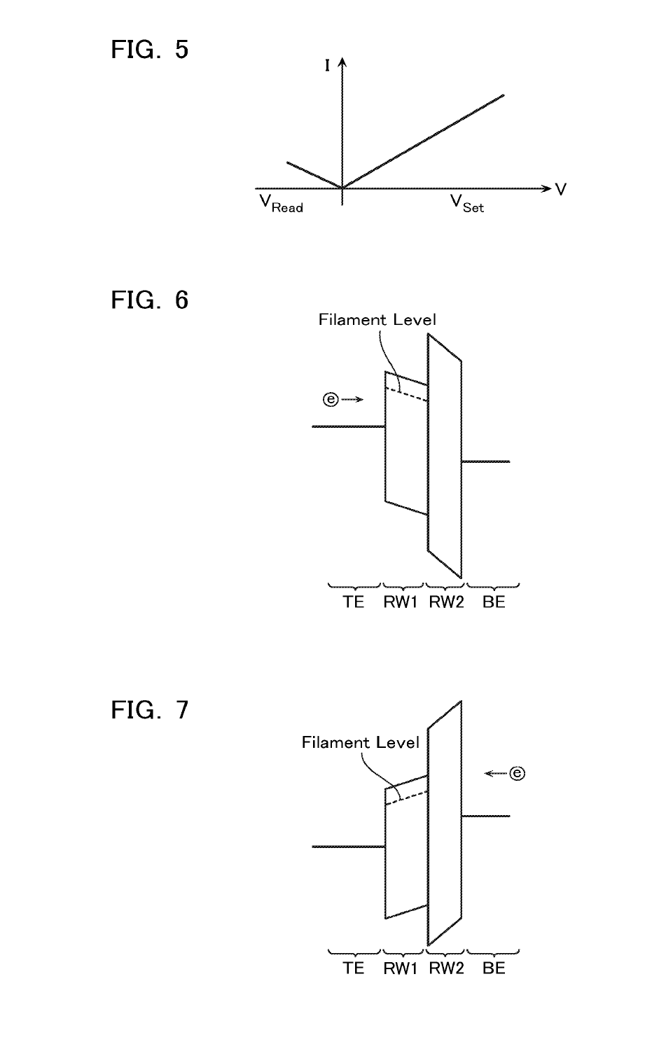

As shown in FIGS. 4A to 4C, in order to suppress this kind of increase in the external applied voltage during the setting operation, there is a need to suppress and reduce the current flowing in the memory cell MC. Moreover, on the other hand, from a viewpoint that the read voltage flowing in the memory cell during read suppresses misread, there is a need to secure above a certain current amount. As shown in FIG. 5, the setting voltage V_{Set} and the read voltage V_{Read} have opposite polarities, hence by utilizing characteristics of the resistance varying element VR according to the present embodiment described below, it becomes possible for these to be individually controlled to achieve both suppression of the setting voltage V_{Set} and securing of the read voltage V_{Read}.

[Characteristics of Resistance Varying Element VR]

Characteristics of the resistance varying element according to the present embodiment will be described using FIGS. 6 and 7.

FIG. 6 is an energy band diagram showing an energy level during the setting operation, of each of parts configuring the resistance varying element VR according to the present embodiment.

A filament due to oxygen deficiency occurs in the first resistance varying film RW1 configured from the likes of hafnium oxide in the resistance varying element VR that has undergone forming. A level of the filament (filament level) shown in FIG. 6 is lower than an energy level of the first resistance varying film RW1, electrons move within the first resistance varying film RW1 via this filament and move within the second resistance varying film RW2 by a tunnel effect, whereby a current flows and a low resistance state (setting state) is maintained. Moreover, the polarity of the applied setting voltage V_{Set} is configured such that a top electrode TE side is low potential and a bottom electrode BE side is high potential. That is, during setting, electrons are injected from the top electrode TE side to the bottom electrode BE side.

In the resistance varying element VR in the present embodiment, the work function of the metal configuring the top electrode TE is larger than the work function of the metal configuring the bottom electrode BE. This means that a vacuum level offset of the top electrode TE becomes comparatively large, and it becomes difficult for electrons to move from the top electrode TE side to the bottom electrode BE side, in other words, it becomes difficult for a current to flow.

Moreover, the fact that it becomes difficult for a current to flow in this way during the setting operation makes it possible for the setting voltage V_{Set} to be applied without the external applied voltage being significantly increased as mentioned above.

On the other hand, during the read operation, there is an energy band diagram of the kind shown in FIG. 7. In this case, conversely to in the case shown in FIG. 6, electrons flow from the bottom electrode BE side to the top electrode TE side. Moreover, the work function of the metal configuring the bottom electrode BE is smaller than the work function of the metal configuring the top electrode TE. Therefore, since the vacuum level offset of the bottom electrode BE side which is an electron injection side during the read operation becomes smaller than during setting, it becomes easier for electrons to move compared to during the setting operation. In other words, it becomes easier for a current to flow. The fact that it becomes easier for a current to flow during the read operation makes it possible for a current amount during the read operation to be secured, and makes it possible for the current to be reliably detected by the sense amplifier.

As described above, it may be understood that the resistance varying element VR according to the present embodiment enables a setting current flowing during setting to be suppressed and reduced, and a read current flowing during read to increase and be secured above a certain level.

Note that during the read operation, if the level of the first resistance varying film RW1 can be lowered, then it becomes easier for electrons to move, and it becomes easier for a current to flow. In order to achieve this, it is preferable for a low permittivity material to be employed in the second resistance varying film RW2. This is because by lowering permittivity of the second resistance varying film, an effect of lowering the level of the first resistance varying film RW1 rises proportionately to a voltage divided to the second varying resistance film RW2.

The first embodiment described an example configured such that electrons are injected from the top electrode TE side to the bottom electrode BE side during the setting operation. However, it is possible to change a configuration of wiring lines connected to the resistance varying element VR, and so on, to configure such that electrons are injected from the bottom electrode BE side to the top electrode TE side during the setting operation. In this case, configurations of each of layers of the resistance varying element VR shown in FIG. 3 are rendered upside down.

### Second Embodiment

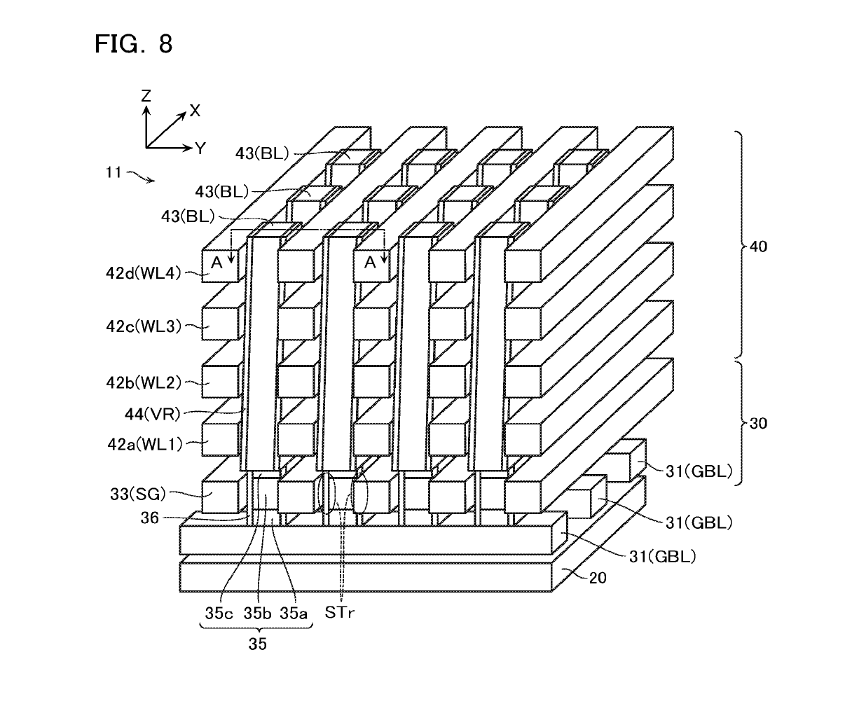

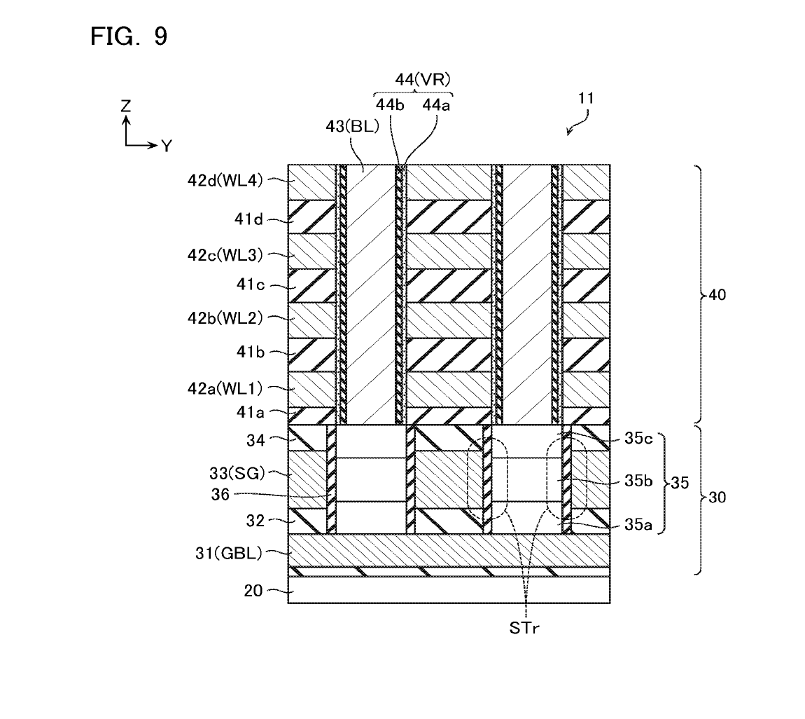

Next, a nonvolatile semiconductor memory device according to a second embodiment will be described using FIGS. 8 and 9. FIG. 8 is a schematic perspective view showing an example of configuration of a memory cell array 11 according to the second embodiment. FIG. 9 is a cross-sectional view of the A-A plane of FIG. 8 seen from the X direction.

As shown in FIGS. 8 and 9, the memory cell array 11 according to the second embodiment includes a select transistor layer 30 and a memory layer 40 stacked on a substrate 20. The select transistor layer 30 functions as a select transistor STr, and the memory layer 40 functions as a plurality of memory cells MC. In addition, a peripheral circuit of the memory cell array according to the second embodiment is configured as shown in FIG. 1. In other words, the control circuit comprises a control circuit that manages the setting operation and the read operation similarly to in the first embodiment.

As shown in FIGS. 8 and 9, the select transistor layer 30 includes a conductive layer 31, an inter-layer insulating layer 32, a conductive layer 33, and an inter-layer insulating layer 34. These conductive layer 31, inter-layer insulating layer 32, conductive layer 33, and inter-layer insulating layer 34 are stacked in a Z direction perpendicular to the substrate 20. The conductive layer 31 functions as a global bit line GBL, and the conductive layer 33 functions as a select gate line SG and a gate of the select transistor STr.

The conductive layers 31 are aligned with a certain pitch in an X direction parallel to the substrate 20, and extend in a Y direction. The inter-layer insulating layer 32 covers an upper surface of the conductive layer 31. The conductive layers 33 are aligned with a certain pitch in the Y direction, and extend in the X direction. The inter-layer insulating layer 34 covers a side surface and upper surface of the conductive layer 33. For example, the conductive layers 31 and 33 are configured by polysilicon. The inter-layer insulating layers 32 and 34 are configured by silicon oxide (SiO₂).

In addition, as shown in FIGS. 8 and 9, the select transistor layer 30 includes a columnar semiconductor layer 35 and a gate insulating layer 36. The columnar semiconductor layer 35 functions as a body (channel) of the select transistor STr, and the gate insulating layer 36 functions as a gate insulating film of the select transistor STr.

The columnar semiconductor layers 35 are disposed in a matrix in the X and Y directions, and extend in a column shape in the Z direction. Moreover, the columnar semiconductor layer 35 contacts an upper surface of the conductive layer 31, and contacts a side surface in the Y direction of the conductive layer 33 via the gate insulating layer 36. Moreover, the columnar semiconductor layer 35 includes an N+ type semiconductor layer 35a, a P+ type semiconductor layer 35b, and an N+ type semiconductor layer 35c that are stacked.

As shown in FIGS. 8 and 9, the N+ type semiconductor layer 35a contacts the inter-layer insulating layer 32 at a side surface in the Y direction of the N+ type semiconductor layer 35a. The P+ type semiconductor layer 35b contacts the side surface of the conductive layer 33 at a side surface in the Y direction of the P+ type semiconductor layer 35b. The N+ type semiconductor layer 35c contacts the inter-layer insulating layer 34 at a side surface in the Y direction of the N+ type semiconductor layer 35c. The N+ type semiconductor layers 35a and 35c are configured by polysilicon implanted with an N+ type impurity, and the P+ type semiconductor layer 35b is configured by polysilicon implanted with a P+ type impurity. The gate insulating layer 36 is configured by silicon oxide (SiO₂), for example.

As shown in FIGS. 8 and 9, the memory layer 40 includes inter-layer insulating layers 41a to 41d and conductive layers 42a to 42d stacked alternately in the Z direction. The conductive layers 42a to 42d function as word lines WL1 to WL4, respectively. When viewed from the Z direction, the conductive layers 42a to 42d are each configured having a pair of comb tooth shapes facing each other in the X direction, for example. The inter-layer insulating layers 41a to 41d are configured by silicon oxide (SiO₂), for example.

In addition, as shown in FIGS. 8 and 9, the memory layer 40 includes a columnar conductive layer 43 and a variable resistance layer 44.

The columnar conductive layers 43 are disposed in a matrix in the X and Y directions, contact upper surfaces of the columnar semiconductor layers 35, and extend in the Z direction. This columnar conductive layer 43 is configured by polysilicon, for example, and functions as the bit line BL.

The variable resistance layer 44 is provided between a side surface in the Y direction of the columnar conductive layer 43 and side surfaces in the Y direction of the inter-layer insulating layers 41a to 41d. In addition, the variable resistance layer 44 is provided between the side surface in the Y direction of the columnar conductive layer 43 and side surfaces in the Y direction of the conductive layers 42a to 42d. Moreover, the variable resistance layer 44 is configured from a stacked structure of a first variable resistance film 44a and a second variable resistance film 44b, and functions as the variable resistance element VR.

In the case of a so-called VBL structure in which memory cells MC utilizing resistance variation are stacked three-dimensionally as in the present embodiment, it results in a plurality of the memory cells MC being connected to the select transistor STr. Thereupon, there is a risk that a leak current flowing into the transistor STr from an unselected memory cell MC increases, giving rise to a problem of setting voltage increase, similarly to in the first embodiment.

Accordingly, the second embodiment adopts a similar configuration to that of the first embodiment for the above-mentioned conductive layers 42a to 42d, first variable resistance film 44a, second variable resistance film 44b, and columnar conductive layer 43.

That is, in the present embodiment, the conductive layers 42a to 42d and the columnar conductive layer 43 are configured such that a work function of a metal configuring the conductive layers 42a to 42d is larger than a work function of a metal configuring the columnar conductive layer 43. Regarding materials thereof, similarly to in the first embodiment, usable as the metal configuring the conductive layers 42a to 42d are the likes of titanium nitride (TiN), platinum (Pt), ruthenium (Ru), or iridium (Ir), for example. Usable as the metal configuring the columnar conductive layer 43 is a metal whose work function is smaller than that of the metal configuring the conductive layers 42a to 42d, such as tungsten nitride (WN) or tantalum nitride (TaN), for example.

Moreover, the first resistance varying film RW1 is configured from a metal oxide film of the likes of hafnium oxide (HfOₓ), for example. The first resistance varying film RW1 is formed by a method such as ALD (Atomic Layer Deposition), for example, and has a thickness which is about 5 nm, for example, but may be appropriately changed in a range of about 2 to 10 nm. Employable as a material besides HfOₓ are a transition metal oxide of the likes of chromium (Cr), tungsten (W), vanadium (V), niobium (Nb), tantalum (Ta), titanium (Ti), zirconium (Zr), scandium (Sc), yttrium (Y), thorium (Th), manganese (Mn), iron (Fe), ruthenium (Ru), osmium (Os), cobalt (Co), nickel (Ni), copper (Cu), zinc (Zn), cadmium (Cd), aluminum (Al), gallium (Ga), indium (In), tin (Sn), lead (Pb), and bismuth (Bi), or an oxide of the likes of a so-called rare earth element from lanthanum (La) to lutetium (Lu).

The second resistance varying film RW2 is configured from a silicon oxide (SiOₓ) film, for example. Similarly to the first resistance varying film RW1, this second resistance varying film RW2 is also formed by the likes of ALD, but has a thickness which is preferably 3 nm or less. This is because, if the thickness ends up exceeding 3 nm, then, as already mentioned, during the memory cell operation, a tunnel effect ends up decreasing and it ends up becoming difficult for electrons to pass through. As a result, there is a risk that deterioration of device characteristics is caused. Moreover, in order to lower a level of the first resistance varying film RW1 during the read operation, it is preferable for a material of low permittivity to be used as the second resistance varying film RW2. For example, the likes of alumina (AlO) or silicon nitride (SiN) may be used, besides the above-described silicon oxide.

Moreover, this embodiment is configured such that electrons are injected from a conductive layers 42a to 42d side to a columnar conductive layer 43 side during the setting operation. In other words, this embodiment is configured such that current flows from a bit line BL side to a word line WL side. Moreover, this embodiment is configured such that during the read operation, current flows from the word line WL side to the bit line BL side, conversely to during the setting operation.

The second embodiment described an example configured such that electrons are injected from the conductive layers 42a to 42d side to the columnar conductive layer 43 side during the setting operation. However, it is possible to change a configuration of wiring lines, and so on, and configure such that electrons are injected from the columnar conductive layer 43 side to the conductive layers 42a to 42d side during the setting operation. In this case, respective configurations and materials configuring the conductive layers 42a to 42d and columnar conductive layer 43 and the first resistance varying film RW1 and second resistance varying film RW2, are reversed.

[Others]

While certain embodiments have been described, these embodiments have been presented by way of example only, and are not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

What is claimed is:

1. A nonvolatile semiconductor memory device, comprising:
a memory cell array; and
a control circuit that applies a voltage to the memory cell array to manage a setting operation and a read operation,
the memory cell array comprising: a first wiring line; a second wiring line intersecting the first wiring line; and a memory cell disposed at an intersection of the first and second wiring lines and including a variable resistance element and a nonlinear element,
the variable resistance element being configured having a first metal film, a first variable resistance film, a second variable resistance film, and a second metal film stacked and disposed therein in this order, and
a work function of the second metal film being smaller than a work function of the first metal film.

2. The nonvolatile semiconductor memory device according to claim 1, wherein
the second variable resistance film is of lower permittivity than the first variable resistance film.

3. The nonvolatile semiconductor memory device according to claim 1, wherein
a thickness of the second variable resistance film is 3 nm or less.

4. The nonvolatile semiconductor memory device according to claim 1, wherein
the first metal film includes any of Ti, Pt, Ru, or Ir.

5. The nonvolatile semiconductor memory device according to claim 1, wherein
the second metal film includes W or Ta, or a nitride of these.

6. The nonvolatile semiconductor memory device according to claim 1, wherein
electrons are injected from a first metal film side to a second metal film side during the setting operation, and
electrons are injected from the second metal film side to the first metal film side during the read operation.

7. A method of controlling a nonvolatile semiconductor memory device, the nonvolatile semiconductor memory device comprising:
a memory cell array; and
a control circuit that applies a voltage to the memory cell array to manage a setting operation and a read operation,
the memory cell array comprising: a first wiring line; a second wiring line intersecting the first wiring line; and a memory cell disposed at an intersection of the first and second wiring lines and including a variable resistance element and a nonlinear element,
the variable resistance element being having a first metal film, a first variable resistance film, a second variable resistance film, and a second metal film stacked and disposed therein in this order, and
a work function of the second metal film being smaller than a work function of the first metal film,
the method comprising:
during the setting operation, injecting electrons from a first metal film side to a second metal film side; and
during the read operation, injecting electrons from the second metal film side to the first metal film side,
with respect to the nonvolatile semiconductor memory device.

8. The method of controlling a nonvolatile semiconductor memory device according to claim 7, wherein
the second variable resistance film is of lower permittivity than the first variable resistance film.

9. The method of controlling a nonvolatile semiconductor memory device according to claim 7, wherein
a thickness of the second variable resistance film is 3 nm or less.

10. The method of controlling a nonvolatile semiconductor memory device according to claim 7, wherein
the first metal film includes any of Ti, Pt, Ru, or Ir.

11. The method of controlling a nonvolatile semiconductor memory device according to claim 7, wherein
the second metal film includes W or Ta, or a nitride of these.

12. A nonvolatile semiconductor memory device, comprising:
a memory cell array including a plurality of memory cells; and
a control circuit that applies a voltage to the memory cell array to manage a setting operation and a read operation,
the memory cell array comprising: a plurality of first conductive layers stacked with a certain pitch in a first direction perpendicular to a substrate and extending in a second direction parallel to the substrate; a memory layer provided commonly to side surfaces of the plurality of first conductive layers and functioning as the memory cell; a second conductive layer electrically connected to the plurality of first conductive layers via the memory layer and extending in the first direction; and a nonlinear element electrically connected to the second conductive layer,
the variable resistance element being configured having a first variable resistance film and a second variable resistance film stacked and disposed therein, and
a work function of the second conductive layer being smaller than a work function of the first conductive layer.

13. The nonvolatile semiconductor memory device according to claim 12, wherein
the second variable resistance film is of lower permittivity than the first variable resistance film.

14. The nonvolatile semiconductor memory device according to claim 12, wherein
a thickness of the second variable resistance film is 3 nm or less.

15. The nonvolatile semiconductor memory device according to claim 12, wherein
the first conductive layer includes any of Ti, Pt, Ru, or Ir.

16. The nonvolatile semiconductor memory device according to claim 12, wherein
the second conductive layer includes W or Ta, or a nitride of these.

17. The nonvolatile semiconductor memory device according to claim 12, wherein
electrons are injected from a first metal film side to a second metal film side during the setting operation, and
electrons are injected from the second metal film side to the first metal film side during the read operation.
